(19) United States
(12) Patent Application Publication
(10) Pub. No.: US 2007/0262474 A1
(43) Pub. Date: Nov. 15, 2007

(54) SEMICONDUCTOR DEVICE AND METHOD OF MANUFACTURING SAME

(76) Inventors: Kunihiro Shiota, Tokyo (JP); Jun Tanaka, Tokyo (JP)

Correspondence Address: WHITHAM, CURTIS & CHRISTOFFERSON & COOK, P.C., 11491 SUNSET HILLS ROAD, SUITE 340, RESTON, VA, 20190, US

(21) Appl. No.: 11/745,739

(22) Filed: May 8, 2007

(30) Foreign Application Priority Data
May 9, 2006 (JP) 2006-130896

(51) Int. Cl. H01L 23/29; H01L 21/00

(52) U.S. Cl. 257/794; 438/112

(57) ABSTRACT

A semiconductor device is provided which is capable of suppressing decreased yields and increased costs, maintaining excellent optical characteristics, reducing secular changes in characteristics to ensure high erliability. After implanting a dopant into a polycrystalline silicon film and activating the implanted dopant and forming a source region, drain region, and channel region, a substrate is exposed to hydrogen gas plasma with a substrate temperature kept within a range between 350° C. and 420° C. and with treating time of 3 minutes to 60 minutes taken. This exposure suppresses a content of occluded water contained in silicon dioxide making up a primary protecting film, which prevents the diffusion of water being an impurity at operational temperatures of a thin film transistor and adverse characteristics on operational characteristics.

### INCORPORTION BY REFERENCE

This application is based upon and claims the benefit of priority from Japanese Patent Application No. 2006-130896, filed on May 9, 2006, the disclosure of which is incorporated herein in its entirely by reference.

### BACKGROUND OF THE INVENTION

1. Field of the Invention

The present invention relates to a semiconductor device and a method for manufacturing the same and more particularly to the semiconductor device including a TFT (Thin Film Transistor) or a like to be formed, as a switching element or a like, for example, on a glass substrate and the method for manufacturing the semiconductor device.

2. Description of the Related Art

Conventionally, a TFT is formed on a glass substrate making up a liquid crystal display panel, organic EL (ElectroLuminescent) display panel, or a like and is used as a switching element, a part of a driving circuit, or a like. The TFT is formed on the glass substrate with a primary protecting film interposed between the TFT and the glass substrate. That is, when the TFT is manufactured by using polycrystalline silicon as its semiconductor active layer, a top-gate-type structure is employed in which a polycrystalline silicon film is formed on the primary protecting film deposited on the glass substrate on which a gate insulating film made of silicon dioxide is then formed and a gate electrode is formed with the gate insulating film being interposed between the gate electrode and the primary protecting film and a source electrode is connected to a source region on the polycrystalline silicon film and a drain electrode is connected to a drain region on the polycrystalline silicon film (see, for example, Japanese Patent Application Laid-open Nos. Hei 09-064365 and Hei 11-003887).

When the TFT is to be manufactured by using the glass substrate which is low-priced and can provide a large area, there is a limitation on a temperature at which the glass substrate is allowed to be processed, that is, at which the TFT is formed. In other words, even if the TFT is manufactured in a low-temperature process, high-reliability of characteristics of the TFT needs to be also ensured. For example, variations in the characteristics such as a gate threshold voltage Vth of the TFT have to be suppressed. To improve the reliability of the TFT, for example, secular changes in its performance characteristics need to be reduced, which is also required for the improvement of stability in operational environments of the TFT when being employed in a liquid crystal display panel, organic EL display panel, or the like. To achieve this, it is necessary to select materials for the TFT including the primary protecting film described above that can provide reduced changes in its characteristics regardless of temperatures at which the materials are processed.

For the above reasons, a silicon dioxide film being comparatively stable in operational environments and presenting less changes in a temperature range for use is used as the primary protecting film. However, even in the case of using the silicon dioxide film, there is a problem; that is, an amount of change in a threshold voltage Vth being one of characteristics of the TFT, which is obtained by the measurement by applying an electric stress on the TFT formed on the glass substrate, increases as time elapses. FIG. 15 shows that an amount of change in a threshold voltage Vth becomes 0.8V at the time lapse of 12,000 sec.

To solve this problem, after the formation of the silicon dioxide film as the primary protecting film on the glass substrate, as shown in FIG. 16, a film made of a material having a high capability of inhibiting the diffusion of impurities and having a comparatively small intra-film impurity concentration such as a silicon oxynitride film is formed on the silicon dioxide film to prevent contamination caused by impurities diffused from the glass substrate, thereby enabling improvement of the reliability of the TFT. That is, a TFT 101, as shown in FIG. 16, is formed on a glass substrate 102 with a primary protecting film 103 interposed between the TFT 101 and the glass substrate 102 and is used as a switching element for a transmission-type liquid crystal display panel 104.

The related art liquid crystal display panel 104 includes a TFT substrate 106 on which a large number of TFTs 101, 101, . . . , a large number of transparent pixel electrodes 105, 105, . . . , the facing substrate 107 placed in a fixed manner to face the TFT substrate 106 with a gap of several μm being sandwiched between the TFT substrate 106 and facing substrate 107, and a liquid crystal layer 108 sealed hermetically in the gap.

The TFT substrate 106 has the glass substrate 102, a silicon dioxide film 103a deposited on the glass substrate 102 and configured to prevent the contamination caused by impurities from the glass substrate 102, the primary protecting film 103 made of a silicon oxynitride film 103b, a semiconductor film 114 made of polycrystalline silicon etched on the primary protecting film 103 so as to have an island structure, on which a source region, drain region, and channel region are formed, a gate insulating film 115 deposited on the semiconductor film 114 and made of a silicon dioxide film, a gate electrode 116 formed in a region corresponding to the channel region on the gate insulating film 115, the first interlayer insulating film 117 made of a silicon dioxide film deposited in a manner to cover the gate insulating film 115 and gate electrode 116, a source electrode 121 formed on the first interlayer insulating film 117 connected through a contact hole 118 to the source region, a drain electrode 122 formed on the first interlayer insulating film 117 connected through a contact hole 119 to the drain region, the second interlayer insulating film 123 made of a silicon nitride film and deposited so as to cover the first interlayer insulating film 117, source electrode 121 and drain electrode 122, a flattened film 124 formed on the second interlayer insulating film 123, the transparent pixel electrode 105 connected to the drain electrode 122 through the contact hole 125. On a layer for the transparent pixel electrode 105 is formed a liquid crystal orientation film 126 so as to cover the layer for the transparent pixel electrode layer 105. The facing substrate 107 is made up of a facing electrode 128 and a transparent insulating substrate 127 in which the facing electrode 128 is formed on the transparent insulating substrate 127. On the facing electrode 128 is formed a liquid crystal orientation film 129 so as to cover the facing electrode 128.

Problems to be solved in the above conventional technology include the decreased yields, increased manufacturing costs, and deterioration in optical characteristics. That is, in the conventional process, a surface portion of the silicon dioxide film is oxynitrized after the formation of the silicon dioxide film, as the primary protecting film, on the glass substrate so that the silicon oxynitride film is formed on a surface of the silicon dioxide film and, as a result, the manufacturing process is made complicated, causing the reduction in yields and the rise in costs. Moreover, the use of the silicon oxynitride film having larger variations in optical characteristics (for example, in a refractive index or a like) for a glass substrate compared with those of the silicon dioxide film causes an adverse effect such as lowering of optical transmittance. Thus, in the formation of a TFT on a glass substrate by using a low-temperature process, it is difficult to suppress the reduction in yields and rise in costs, to maintain optical characteristics in an excellent condition, and to reduce secular changes in characteristics to ensure high reliability.

### SUMMARY OF THE INVENTION

In view of the above, it is an object of the present invention to provide a semiconductor device capable of suppressing the reduction in yields and rise in costs, maintaining optical characteristics in an excellent condition, and reducing secular changes in characteristics, and a method for manufacturing the semiconductor device.

According to a first aspect of the present invention, there is provided a method for manufacturing a semiconductor device including:

a process of forming a primary protecting film on a substrate; and

a process of forming an active layer on the formed primary protecting film,
wherein hydrogen plasma processing is added by which the substrate, on which at least the primary protecting film is formed, is exposed to hydrogen plasma and occluded water contained in the primary protecting film is desorbed and removed.

In the foregoing, a preferable mode is one wherein, in the hydrogen plasma processing, the substrate is exposed to hydrogen plasma by setting a temperature of the substrate to be within a range between 350° C. and 420° C.

Also, a preferable mode is one wherein, in the hydrogen plasma processing, treating time is set to be within a range of 3 minutes to 60 minutes.

Also, a preferable mode is one wherein the hydrogen plasma processing is performed so as to acquire film quality of the primary protecting film to a degree to which a content of occluded water is less than that of structural water.

Also, a preferable mode is one wherein the hydrogen plasma processing is performed in a manner in which, in the hydrogen plasma processing, atoms each having a mass number of 18 that are desorbed from the primary protecting film at a time of being heated is counted and in a manner in which, in an increased temperature—desorbed amount profile obtained by Thermal Desorption Spectroscopy, a first peak of a desorbed amount appears in the first temperature range between at least 150° C. and 250° C. and a second peak of a desorbed amount appears in the second temperature range between 250° C. and 400° C.

Also, a preferable mode is one that wherein includes a protecting film forming process of forming the primary protecting film on the substrate;

an active layer forming process of forming an active layer made of a semiconductor film so as to have a desired pattern on the primary protecting film;

an insulating forming process of forming a gate insulating film on the active layer;

a gate electrode forming process of forming a gate electrode on the gate insulating film;

an impurity implanting process of implanting an impurity ion into the active layer using the gate electrode as a mask; and

an annealing process of activating the impurity ion implanted into the active layer by specified heating treatment to form a source region and drain region;

wherein the hydrogen plasma processing is performed after the annealing process.

Also, a preferable mode is one wherein the hydrogen plasma processing is performed, after the formation of the primary protecting film and before the formation of the active layer.

Also, a preferable mode is one wherein the primary protecting film having a two-layered structure is formed by depositing an upper protecting film made of silicon nitride after the formation of a primary protecting film made of silicon dioxide.

Also, a preferable mode is one wherein the substrate is made up of a glass substrate.

Also, a preferable mode is one wherein the semiconductor is made of polycrystalline silicon.

Also, a preferable mode is one wherein, by using a Low Pressure Chemical Vapor Deposition method using silane and oxygen as material gas or a Plasma Enhanced Vapor Deposition method using silane and di-nitrogen monoxide as material gas, a silicon dioxide film serving as the primary protecting film is formed on the substrate and the active layer made of the semiconductor is formed on the primary protecting film and, at least after the formation of the active layer, the hydrogen plasma processing is performed.

According to a second aspect of the present invention, there is provided a semiconductor device including:

a primary protecting film formed on a substrate; and

an active layer made of a semiconductor formed on the primary protecting film,

wherein the primary protecting film has a characteristic in which a content of occluded water is less than that of structural water.

According to a third aspect of the present invention, there is provided a semiconductor device including:

a primary protecting film formed on a substrate; and

an active layer made of a semiconductor formed on the primary protecting film;

wherein, in an increased temperature—desorbed amount profile obtained by Thermal Desorption Spectroscopy in which atoms each having a mass number of 18 that are desorbed from the primary protecting film at a time of being heated is counted, a film quality of the primary protecting film is achieved in a manner in which a first peak of desorbed amounts appears in the first temperature range between at least 150° C. and 250° C., in which a second peak of desorbed amount appears in the second temperature range between 250° C. and 400° C. and in which the first peak appearing in the first temperature range is less than the second peak appearing in the second temperature range.

In the foregoing, a preferable mode is one wherein the semiconductor device is obtained by exposing the substrate, on which at least the primary protecting film is formed, to hydrogen plasma and by performing hydrogen plasma processing by which a content of occluded water contained in the primary protecting film is desorbed and removed.

Also, a preferable mode is one wherein the semiconductor device is obtained by performing hydrogen plasma processing to expose the substrate, on which at least the primary protecting film is formed, to hydrogen plasma so as to desorb and remove occluded water contained in the primary protecting film to a degree to which the first peak appearing within the first temperature range is less than the second peak appearing within the second temperature range in the increased temperature—desorbed amount profile.

Also, a preferable mode is one wherein the hydrogen plasma processing is performed by setting a temperature of the substrate on which the primary protecting film is formed to be between 350° C. and 420° C. and by exposing the substrate to hydrogen plasma.

Also, a preferable mode is one wherein, in the hydrogen plasma processing, treating time is set to be within a range of 3 minutes to 60 minutes.

Also, a preferable mode is one wherein the primary protecting film includes a silicon dioxide film formed on the substrate by a Low Pressure Chemical Vapor Deposition method using silane and oxygen as material gas or by a Plasma Enhanced Chemical Vapor Deposition method using silane and di-nitrogen monoxide as material gas.

Also, a preferable mode is one wherein the substrate includes a glass substrate.

Also, a preferable mode is one wherein the semiconductor is made of polycrystalline silicon.

Furthermore, a preferable mode is one wherein the primary protecting film includes a two-layered structure having a lower layer protecting film made of silicon dioxide and an upper layer protecting film made of silicon nitride.

With the above configurations, by exposing the substrate, on which at least the primary protecting film is formed, to hydrogen plasma so as to desorb and remove occluded water contained in the primary protecting film, the diffusion of impurities from the substrate and primary protecting film can be prevented without the need for the formation of a silicon oxynitrized film and, therefore, decreased yields and increased costs can be suppressed and optical characteristics can be maintained in an excellent condition and secular changes in characteristics can be reduced, which ensures high reliability of the semiconductor device.

### BRIEF DESCRIPTION OF THE DRAWINGS

The above and other objects, advantages, and features of the present invention will be more apparent from the following description taken in conjunction with the accompanying drawings in which:

FIG. 1 is a cross-sectional view of configurations of a liquid crystal display panel using a TFT as a switching element according to a first exemplary embodiment of the present invention;

FIG. 2 is a diagram showing a TDS (Thermal Desorption Spectroscopy) profile of a primary protecting film used in the TFT according to the first exemplary embodiment of the present invention;

FIGS. 3A to 3E are process diagrams explaining a method of manufacturing the TFT according to the first exemplary embodiment of the present invention;

FIGS. 4A to 4E are also process diagrams explaining the method of manufacturing the TFT according to the first exemplary embodiment of the present invention;

FIGS. 5A to 5D are also process diagrams explaining the method of manufacturing the TFT according to the first exemplary embodiment of the present invention;

FIGS. 6A and 6B are also process diagrams explaining the method of manufacturing the TFT according to the first exemplary embodiment of the present invention;

FIG. 7 is a graph explaining secular changes in characteristics of the TFT according to the first exemplary embodiment of the present invention;

FIG. 8 is a graph showing a TDS profile of the primary protecting film obtained when no hydrogen plasma process is performed according to the first exemplary embodiment of the present invention;

FIGS. 9A to 9D are process diagrams explaining a manufacturing method of a TFT according to a second exemplary embodiment of the present invention;

FIG. 10 is a cross-sectional view showing configurations of a liquid crystal display panel using a TFT as a switching element according to a third exemplary embodiment of the present invention;

FIG. 11 is a block diagram of a liquid crystal projector using, as a light valve, a liquid crystal display panel according to a fourth exemplary embodiment of the present invention;

FIG. 12 is a diagram explaining configurations of the same liquid crystal projector according to the fourth exemplary embodiment of the present invention;

FIG. 13 is an equivalent circuit diagram for explaining configuration of the same light valve in the liquid crystal projector according to the fourth exemplary embodiment of the present invention;

FIG. 14 is also an equivalent circuit diagram for explaining configuration of the same light valve in the liquid crystal projector according to the fourth exemplary embodiment of the present invention;

FIG. 15 is a diagram explaining a technology according to related art; and

FIG. 16 is also a diagram explaining the technology according to the related art.

### DETAILED DESCRIPTION OF EXEMPLARY EMBODIMENTS

Best modes of carrying out the present invention will be described in further detail using various embodiments with reference to the accompanying drawings. By exposing a substrate, on which at least a primary protecting film is formed, to hydrogen plasma so as to desorb and remove occluded water contained in the primary protecting film, an object of preventing the diffusion of impurities from the substrate and primary protecting film, suppressing decreased yields and increased costs, maintaining excellent optical characteristics, reducing secular changes in characteristics to ensure high reliability is achieved.

### First Exemplary Embodiment

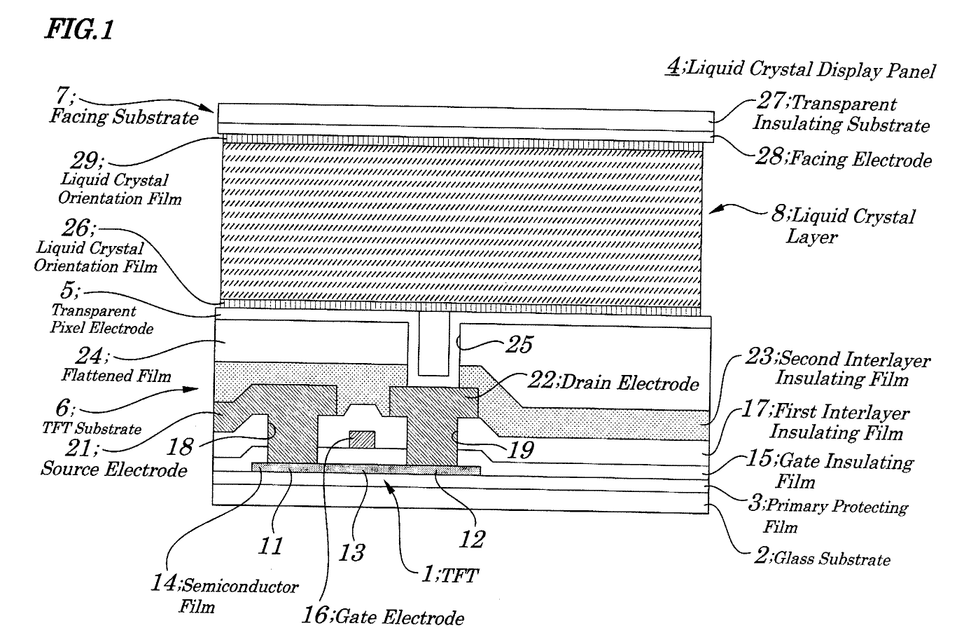

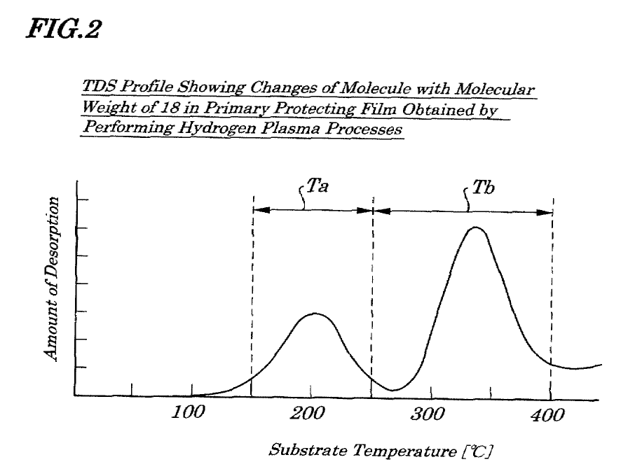

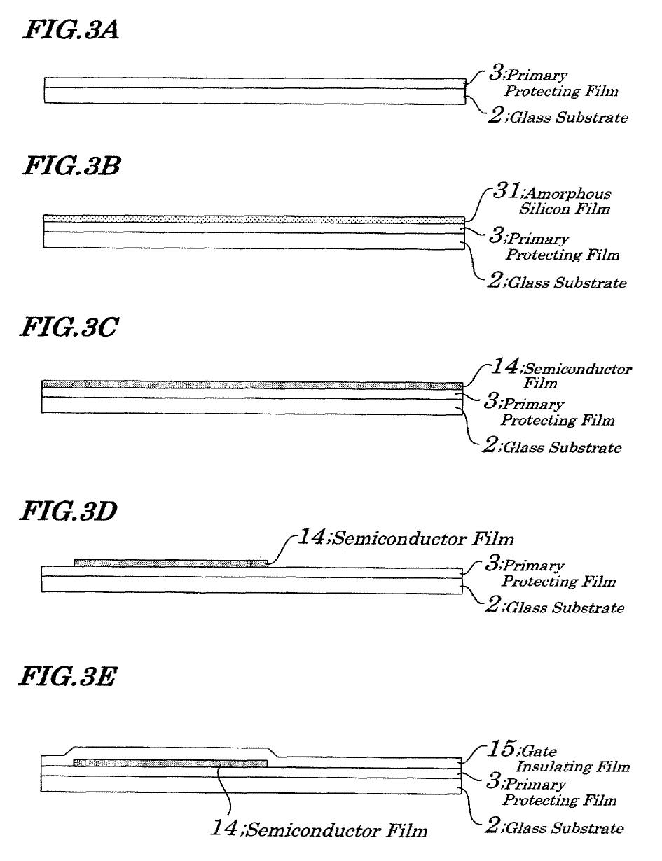

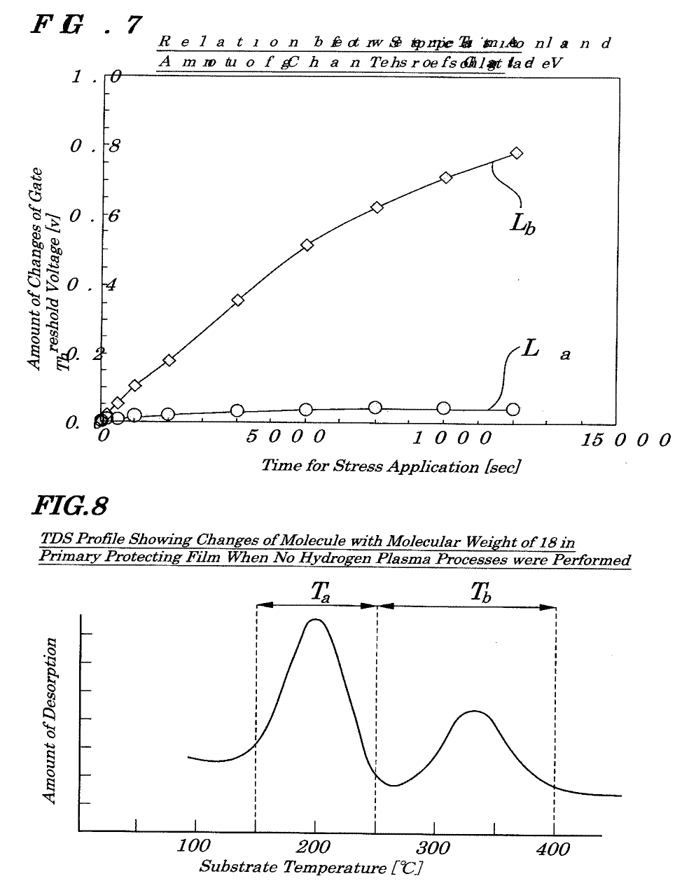

FIG. 1 is a cross-sectional view of configurations of a transmission-type liquid crystal display panel using a TFT as a switching element according to the first exemplary embodiment of the present invention. FIG. 2 is a diagram showing a TDS profile of a primary protecting film in the TFT of the first exemplary embodiment. FIGS. 3 to 6 are process diagrams explaining a method of manufacturing the TFT of the first exemplary embodiment. FIG. 7 is a diagram explaining secular changes in characteristics of the TFT of the first exemplary embodiment. FIG. 8 is a diagram showing the TDS profile of the primary protecting film obtained when no hydrogen plasma processing is performed.

The TFT 1 of the first exemplary embodiment, as shown in FIG. 1, is formed on a glass substrate 2 with the primary protecting film 3 being interposed between the TFT 1 and the glass substrate 2 which is used as a switching element or a like, for example, in the transmission-type liquid crystal display panel 4. The transmission-type liquid crystal display panel 4 includes a TFT substrate 6 on which a large number of TFTs 1, 1, . . . , and a large number of transparent pixel electrodes 5, 5, . . . , are formed, a facing substrate 7 placed in a fixed manner to face the TFT substrate 6 with a gap of several μm being sandwiched between the TFT 6 and the facing substrate 7, a liquid crystal layer 8 sealed hermetically in the above gap, and a pair of polarizers (not shown) placed outside the TFT substrate 6 and the facing substrate 7.

The TFT substrate 6 has the glass substrate 2, the primary protecting film 3 made of a silicon dioxide (SiO₂) film to prevent contamination caused by B (boron), Na (sodium), or a like diffused from the glass substrate 2, a semiconductor film 14 made of polycrystalline silicon (p-Si) etched on the primary protecting film 3 so as to have an island structure on which a source region 11, a drain region 12, and a channel region 13 are formed, a gate insulating film 15 made of a silicon dioxide film deposited on the semiconductor film 14, a gate electrode 16 made of WSI (tungsten silicide), Cr (chromium), Al (aluminum), or a like formed on a region corresponding to the channel region 13 on the gate insulating film 15, a first interlayer insulating film 17 made of a silicon dioxide film deposited to cover the gate insulating film 15 and the gate electrode 16, a source electrode 21 formed on the first interlayer insulating film 17 connected to the source region 11 through a contact hole 18, a drain electrode 22 formed on the first interlayer insulating film 17 connected to the drain region 12 through a contact hole 19, a second interlayer insulating film 23 made of a silicon nitride film formed in a manner to cover the first interlayer insulating film 17, the source electrode 21, and the drain electrode 22, a flattened film 24 made of an organic material such as an acrylic resin formed on the second interlayer insulating film 23, and the transparent pixel electrode layer (ITO [Indium Tin Oxide] film) 5 connected to the drain electrode 22 through a contact hole 25.

That is, the TFT 1 has the semiconductor film 14 on which the source region 11, drain region 12, and channel region 13 are formed, the gate insulating film 15 made of a silicon dioxide film deposited on the semiconductor film 14, and the gate electrode 16 formed in the region corresponding to the channel region 13 on the gate insulating film 15. On the transparent pixel electrode layer 5 is formed a liquid crystal orientation film 26 in a manner to cover the transparent pixel electrode layer 5. Moreover, the facing substrate 7 is configured so that a facing electrode 28 is formed on a transparent insulating substrate 27. On the facing electrode 28 is formed a liquid crystal orientation film 29 in a manner to cover the facing electrode 28. The TFT substrate 6 and facing substrate 7 are so arranged that a liquid crystal orientation film 26 faces the liquid crystal orientation film 29 and the liquid crystal layer 8 is sandwiched between the liquid crystal orientation film 26 and the liquid crystal orientation film 29.

The primary protecting film 3 of the embodiment is made of a silicon dioxide film whose content of occluded water described later is reduced. An analysis of the sample (the primary protecting film used in the embodiment) is made by using a TDS ((Thermal Desorption Spectroscopy) method. That is, an atom (or molecule) having a specified mass number (or molecular weight) that is desorbed from the sample when being heated in a specified high vacuum and an amount of the desorption were analyzed using a mass spectrometer and changes of the sample relative to temperatures were evaluated based on results from the TDS analysis to produce a TDS profile showing a relation between the raised temperature and the desorbed amount. As shown in the TDS profile in FIG. 2, the primary protecting film 3 is formed in a manner in which a peak of the desorbed amount of a molecule (H₂O) having a molecular weight of 18 from the primary protecting film 3, that is, from silicon dioxide appears within an occluded water desorption temperature range Ta between 150° C. and 250° C. and within a structural-water desorption temperature range Tb between 250° C. and 400° C. and in a manner in which the peak value (desorption amount) occurring within the occluded-water desorption temperature range Ta is less than the peak value occurring within the structural-water desorption temperature range Tb. Moreover, the vertical axis of the TDS profile shows a relative value of the amount of desorption and the scale is graduated in a given manner.

The peak of the desorption amount appearing within the occluded-water desorption substrate temperature range Ta represents the peak of the desorbed amount of H₂O molecules (occluded water) being hydrogen-bonded to liquid H₂O or Si—OH trapped in a large number of rings of Si—O and the peak of the desorption amount appearing within the structural-water desorption temperature range Tb means the peak of the desorbed amount of H₂O molecules (structural water) caused by Si—OH groups contained in excessive Si atoms occurring at a time of deposition.

An ultimate temperature of the TFT 1 during operations is, even when estimated high, 200° C. and, therefore, by using the silicon dioxide film, as the primary protecting film 3, formed so that the peak value (desorbed amount) occurring within the occluded-water desorption temperature range Ta is less than the peak value occurring within the structural-water desorption temperature range Tb, in other words, by using the silicon dioxide film whose content of occluded water is reduced, it is made possible to prevent the diffusion of water being as an impurity from the primary protecting film 3 through the semiconductor film 14 in particular, and to avoid adverse effects on operational characteristics of the TFT 1 and, as a result, to prevent degradation of reliability of the semiconductor device.

Next, the method for manufacturing the TFT 1 of the embodiment is described by referring to FIGS. 3A-3E to 6A-6B. First, the primary protecting film 3 made of silicon dioxide is deposited on the glass substrate 2 so as to be about 150 nm in thickness by performing an LPCVD (Low Pressure Chemical Vapor Deposition) method using monosilane and oxygen as material gas or by performing a PECVD (Plasma Enhanced Vapor Deposition) method using monosilane and nitrous oxide as material gas

Next, as shown in FIG. 3B, an amorphous silicon (a-Si) film 31 is deposited so as to be 0.03 μm to 0.06 μm in thickness on the primary protecting film 3 by the LPCVD method or the PECVD method. Then, as shown in FIG. 3C, by implanting a specified amount of a dopant, according to an ion implanting method, into a region on the amorphous silicon film 31 where the channel region 13 is formed and the semiconductor film 14 made of polycrystalline silicon (p-Si) is formed by annealing.

Then, as shown in FIG. 3D, a patterned resist film is formed on the semiconductor film 14 made of a polycrystalline film by photolithography technology and an active layer of the TFT 1 is formed by dry-etching processes on the semiconductor film 14 made of a polycrystalline silicon film, using the resist film as a mask, so as to have an island structure. Next, as shown in FIG. 3E, a gate insulating film 15 made of silicon dioxide with a film thickness of about 0.1 μm is deposited by the LPCVD or PECVD in a manner to cover the semiconductor film 14 made of the polycrystalline silicon film etched so as to have the island structure.

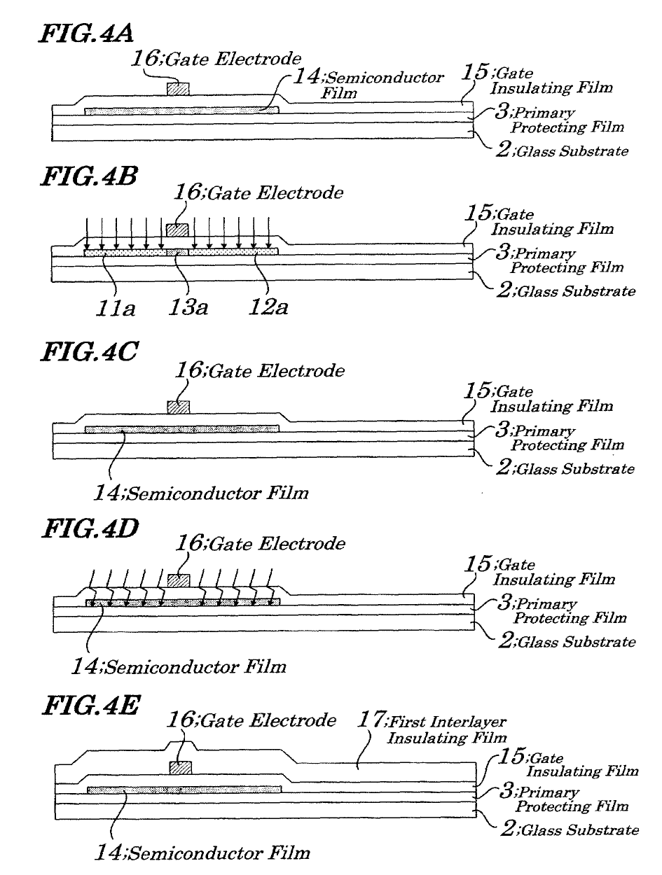

Then, as shown in FIG. 4A, a gate wiring material made of Wsi (tungsten silicon), Cr (chromium), Al (aluminum), or a like is formed in a region corresponding to a forming region 13a for a channel region 13 on the gate insulating film 15 and a gate electrode 16 is formed by an etching method and, for example, a wet-etching method using the patterned resist as a mask. Next, as shown by FIG. 4B, by using the gate electrode 16 as a mask, a desired amount of a dopant such as a phosphorus (P) ion, boron (B) ion, or a like is implanted into regions 11a and 12a for forming a source region 11 and drain region 12 on the semiconductor film 14 made of the polycrystalline silicon film. Then, as shown in FIG. 4C, heating treatment is performed by a furnace annealing method, laser annealing method, or a like at heating temperatures ranging from 450° C. to 550° C. for 1 hour to 4 hours to activate the implanted dopant for the formation of the source region 11 and drain region 12. At this point of time, the channel region 13 is formed immediately below the gate electrode 16.

Next, the substrate is exposed to hydrogen gas plasma by using, for example, a plasma CVD equipment, keeping the substrate temperature (temperature of the glass substrate) at between 350° C. to 420° C. for 1 to 4 hours. Here, if the substrate temperature exceeds 420° C., an amount of hydrogen that is desorbed from the primary protecting film exceeds an amount of hydrogen ions that enter the primary protecting film 3 by the effect of exposure of the substrate to hydrogen plasma and, as a result, no effect of removing occluded water is obtained and the film quality of the primary protecting film 3 is degraded. Moreover, if the substrate temperature is less than 350° C., the effect of the hydrogen plasma processing is reduced and, for example, the removal of the occluded water by the hydrogen plasma processing is not expected.

The hydrogen plasma processing improves the film quality of the silicon dioxide film making up the primary protecting film 2 and gate insulating film 15 as described later and, in the profile showing a relation between temperatures and an amount of desorption obtained by the PDS analysis on the primary protecting film 3, a peak of the desorbed amount of a molecule (H₂O) having a molecular weight of 18 that is desorbed from the primary protecting film (silicon dioxide) appears within the occluded-water desorption temperature range Ta between 150° C. and 250° C. and within the structural-water desorption temperature range Tb between 250° C. and 400° C., and further the peak value (desorbed amount) occurring within the occluded-water desorption temperature range Ta is less than the peak value occurring within the structural-water desorption temperature range Tb (see FIG. 2).

That is, the content of occluded water in the silicon dioxide film making up the primary protecting film 3 is suppressed, which can prevent the diffusion of water being an impurity from the primary protecting film 3 into the semiconductor film 14 in particular at operational temperatures of the TFT 1 and can avoid adverse effects on operational characteristics. Moreover, the activation processing and hydrogen plasma processing may be performed, alternatively, after the formation of the first interlayer insulating film 17.

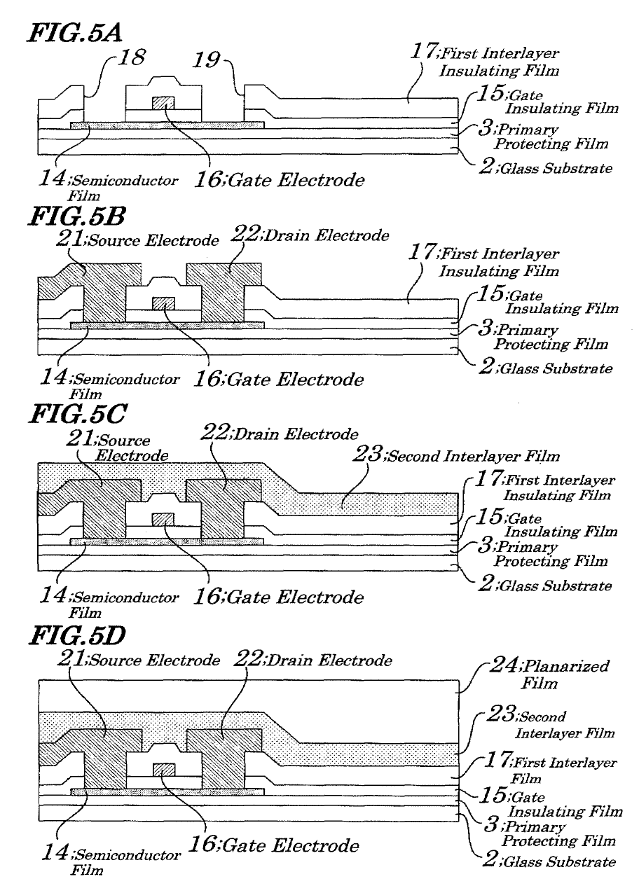

Then, as shown in FIG. 4E, the first interlayer insulating film 17 made of a silicon dioxide film with its film thickness of about 0.4 μm is deposited by the PECVD method. Next, as shown in FIG. 5A, the contact holes 18 and 19 are formed by selectively etching the gate insulating film 15 and first interlayer insulating film 17 placed in an upper portion of the source region 11 and drain region 12 both being made of the silicon dioxide film, using a resist as a mask and by a dry etching method or by combined use of the dry and wet etching methods.

Then, a metal film made of a metal material such as Al or a like is deposited by a sputtering method. Next, as shown in FIG. 5B, the source electrode 21 and drain electrode 22 connected respectively to the source region 11 and drain region 12 are formed by etching the metal film by employing the dry etching method or wet etching method using the patterned resist as a mask. Then, as shown in FIG. 5C, the second interlayer insulating film 23 made of silicon nitride with its film thickness of about 0.4 μm is deposited in a manner to cover the first interlayer insulating film 17, source electrode 21, and drain electrode 22. Next, as shown in FIG. 5D, an organic material made of an acrylic resin is coated on the second interlayer insulating film 23 to form a flattened film 24 with its film thickness of about 1.2 μm.

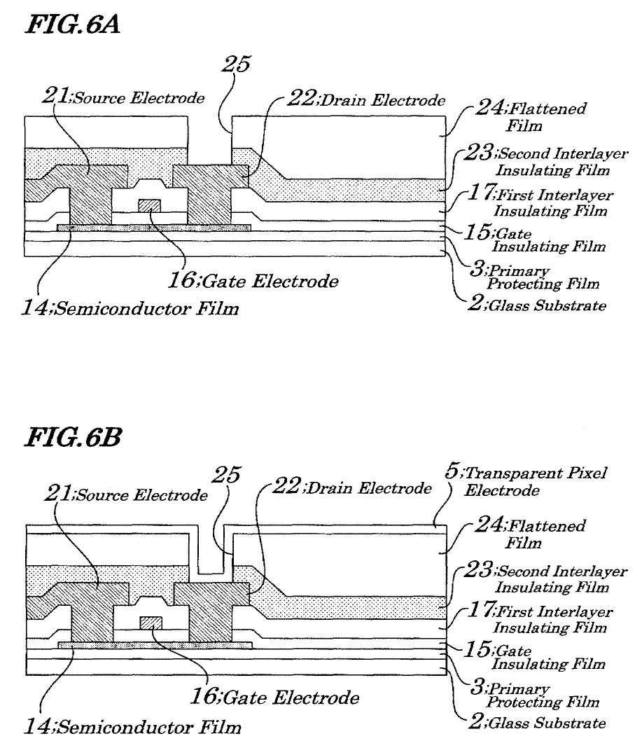

Then, as shown in FIG. 6A, the flattened film 24 and the second interlayer film 23 formed in an upper portion of the drain electrode 22 are etched to form the contact hole 25. Next, as shown in FIG. 6B, an ITO film is deposited by performing sputtering and is then patterned so as to be of a pixel electrode shape to form the transparent pixel electrode 5. Thus, the TFT substrate 6 on which a large number of top-gate type TFTs 1, 1, . . . on the glass substrate 2 is obtained. The TFT 1 is used, for example, as a switching element or part of a driving circuit in transmission-type and active-matrix type liquid crystal display devices.

In the TDS profile of the primary protecting film shown in FIG. 2 which represents the relation between a temperature and an amount of desorption obtained after hydrogen plasma process is performed, the peak of the amount of desorption of a molecule (H₂O) having a molecular weight of 18 from the primary protecting film 3 (made of silicon dioxide) appears within the occluded-water desorption substrate temperature range Ta between 150° C. and 250° C. and within the structural-water desorption temperature range Tb between 250° C. and 400° C., and the peak value (desorbed amount) occurring within the occluded-water desorption substrate temperature range Ta is less than the peak value occurring within the structural-water desorption temperature range Tb.

As described above, the peak of the desorbed amount appearing within the occluded-water desorption temperature range Ta represents the peak of the desorption amount of H₂O molecules (occluded water) being hydrogen-bonded to liquid H₂O or Si—OH trapped in a large number of rings of Si—O and the peak of the desorption amount appearing within the structural-water desorption temperature range Tb represents the peak of the desorption amount of H₂O molecules (structural water) caused by Si—OH groups contained in excessive Si molecules occurring at a time of deposition. It is understood that the hydrogen plasma processing has served to improve the film quality of the primary protecting film 3 and the small peak caused by the desorption of the occluded water has served to suppress the content of the occluded water in silicon dioxide making up the primary protecting film 3. This can prevent the diffusion of water being an impurity, which leads to adverse effects on operational characteristics of the TFT 1, from the primary protecting film 3 into the semiconductor film 14 in particular at operational temperatures of the TFT 1.

A gate threshold voltage Vth being a characteristics of the TFT 1 was measured by applying an electric stress to the TFT 1 formed on the glass substrate 2. As shown by the regular line graph in FIG. 7, after the voltage Vth increased a little in time lapse up to 8,000 sec, no change occurs. Even after the time lapse up to 12,000 sec, the amount of change was less than 0.05V. Thus, secular changes in characteristics occur little.

In contrast, in the TDS profile of the TFT which represents the relation between a temperature and an amount of desorption obtained when no hydrogen plasma process is performed, as shown in FIG. 8, the peak of the amount of desorption of a molecule (H₂O) having a molecular weight of 18 from the primary protecting film 3 (made of silicon dioxide) appears within the occluded-water desorption substrate temperature range Ta between 150° C. and 250° C. and within the structural-water desorption temperature range Tb between 250° C. and 400° C., however, the peak value occurring within the occluded-water desorption substrate temperature range Ta is larger than the peak value occurring within the structural-water desorption temperature range Tb. Moreover, in FIG. 8, the vertical axis of the TDS profile shows a relative value of the amount of desorption and the scale is graduated in a given manner. In the case of no hydrogen plasma processing, the film quality of the primary protecting film 3 remains unchanged and, since the peak caused by the desorption of occluded water is large, the content of the occluded water in silicon dioxide making up the primary protecting film is relatively much. This causes water to be diffused from the primary protecting film as an impurity into the semiconductor film at operational temperatures of the TFT, which leads to adverse effects on operational characteristics.

On the other hand, a gate threshold voltage Vth being a characteristic of the TFT was measured by applying an electric stress to the conventional TFT in which a primary protecting film remaining unstable with no hydrogen plasma processes performed was formed on the glass substrate 2. As shown by the regular line graph in FIG. 7, After the time lapse up to 12,000 sec, the amount of change was about 0.08V. Thus, secular changes in characteristics occur little. Thus, the content of occluded water in the silicon dioxide film making up the primary protecting film 3 is much suppressed. It is estimated that the suppression of the content of the occluded water in the silicon dioxide film occurs from the results from the prevention of the diffusion of water being an impurity from the primary protecting film into the semiconductor film 14 at operational temperatures of the TFT and from the avoidance of the adverse effects on the operational characteristics of the TFT.

As described above, according to the first exemplary embodiment, after performing the annealing process to activate the dopant implanted in the source region 11, drain region 12, and channel region 13, by performing hydrogen plasma processing in which the primary protecting film 3 is exposed to hydrogen plasma with the substrate temperature (temperature of glass substrate 2) kept within a range from 350° C. and 420° C. and with 3 minutes to 60 minutes taken as treating time, the content of the occluded water in the silicon dioxide film serving as the primary protecting film 3 is reduced, thus making it possible to prevent the diffusion of water being an impurity from the primary protecting film 3 into the semiconductor film 14 in particular.

That is, the silicon dioxide film serving as the primary protecting film 3 in the embodiment is formed so that, in the TDS profile of the primary protecting film, the peak of the amount of desorption of a molecule (H₂O) having a molecular weight of 18 from the primary protecting film 3 (made of silicon dioxide) appears within the occluded-water desorption temperature range Ta between 150° C. and 250° C. and within the structural-water desorption temperature range Tb water between 250° C. and 400° C. and the peak value (desorbed amount) occurring within the occluded-water desorption substrate temperature range Ta is less than the peak value occurring within the structural-water desorption temperature range Tb and, therefore, the content of occluded water can be suppressed and the diffusion of water being an impurity from the primary protecting film 3 into the semiconductor film 14 can be prevented.

Moreover, by employing the primary protecting film 3 described above, the contamination caused boron (B), sodium (Na), or a like diffused from the glass substrate 2 can be prevented. As a result, adverse effects on operational characteristics of the TFT can be avoided and secular changes of characteristics can be suppressed, thereby achieving high reliability of the TFT. Thus, probability of occurrence of operating failures of liquid crystal display devices using the liquid crystal display panel made up of the TFT of the present invention can be reduced.

Moreover, by maintaining the substrate temperature within the range between 350° C. and 420° C. and by performing hydrogen gas plasma processing, the content of occluded water contained in silicon dioxide film serving as the primary protecting film 3 can be reliably reduced. That is, if the substrate temperature is set so as to proceed 420° C., the amount of hydrogen being desorbed from the primary protecting film 3 is larger than the amount of hydrogen ions that enter the primary protecting film by exposing the substrate to hydrogen plasma, which, as a result, makes it impossible to remove occluded water. However, according to the embodiment, the substrate temperature is maintained within the range between 350° C. and 420° C., which allows the occluded water to be removed. If the substrate temperature is set to be less than 350° C., the efficiency of hydrogen plasma processing is reduced, however, according to the embodiment, the substrate temperature is maintained within the range between 350° C. and 420° C., which allows the occluded water to be effectively removed.

Also, in the conventional technology, to prevent the diffusion of an impurity such as boron (B), sodium (Na), or a like diffused from a glass substrate, after a silicon dioxide film serving as a primary protecting film is formed on the glass substrate, a surface of the silicon dioxide film is oxynitrized. However, according to the embodiment, the conventional method as described above is not employed and, therefore, there is no fear of making processes complicated and of causing lowered yields and increased costs. Additionally, by using a silicon oxynitrized film having a large difference in optical characteristics (reflectivity or a like) relative to the silicon oxynitrized film and glass substrate, such adverse effects as lowering optical transmittance can be avoided.

Thus, according to the first exemplary embodiment, lowered yields and increased costs can be suppressed while maintaining excellent optical characteristics and suppressing secular changes in characteristics and, as a result, high reliability of the TFT can be ensured.

### Second Embodiment

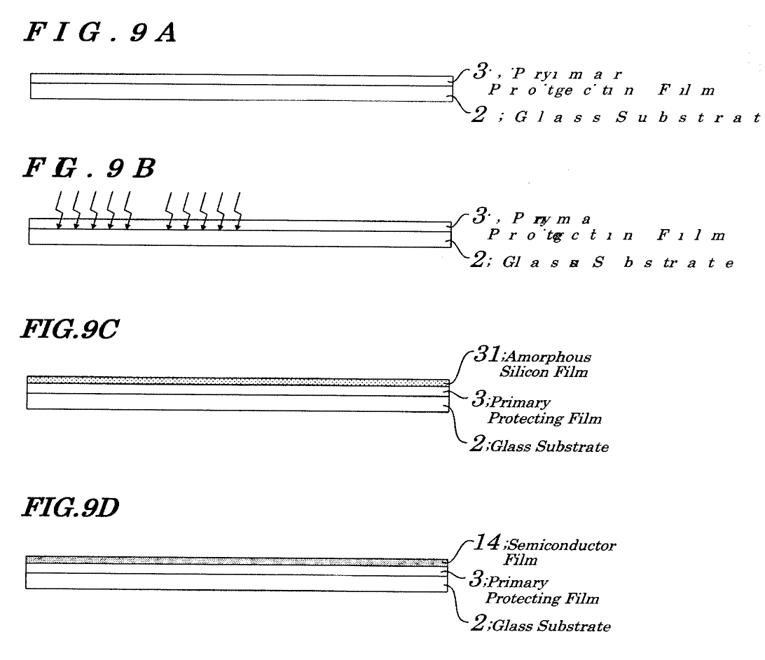

FIG. 9 is a process diagram explaining a manufacturing method of a TFT according to a second embodiment of the present invention. The TFT of the second embodiment differs from that of the first exemplary embodiment in that hydrogen plasma processing is performed not only immediately after the annealing processing but also immediately after the formation of the primary protecting film 3. Configurations other than described above are approximately the same as those of the first exemplary embodiment and, in FIG. 9, same reference numbers are assigned to components having the same functions as in the first exemplary embodiment in FIG. 3 and their descriptions are described simply accordingly.

First, as shown in FIG. 9A, a primary protecting film 3 made of silicon dioxide with its film thickness of about 150 nm is deposited on a glass substrate 2 by an LPCVD method using monosilane and oxygen as material gas or by an PECVD method using monosilane and nitrous oxide as material gas. Next, as shown in FIG. 9B, hydrogen plasma processes are performed, with a substrate temperature (temperature of the glass substrate 2) kept within a range between 350° C. and 420° C. and with 2 minutes to 5 minutes taken as treating time, to expose the substrate to hydrogen gas plasma.

Then, as shown in FIG. 9C, an amorphous silicon (a-Si) film with its film thickness of 0.03 μm] to 0.6 μm is deposited on the primary protecting film 3 by the LPCVD method or PECVD method. Then, as shown in FIG. 9D, a semiconductor film 14 made of polycrystalline silicon (p-Si) by implanting a desired amount of dopants into a channel forming region on the amorphous silicon film by an ion implanting method and then by performing a laser annealing process. Thereafter, the same processing as in the first exemplary embodiment is performed.

Thus, according to the configurations of the second embodiment, the same effect as obtained in the first exemplary embodiment described above can be achieved. In addition, the hydrogen plasma processing is performed not only immediately after the annealing processing but also immediately after the formation of the primary protecting film 3 and, therefore, further improved changes of the quality of the primary protecting film 3 are made and secular changes in characteristics are further suppressed, thereby enabling high reliability to be ensured.

### Third Embodiment

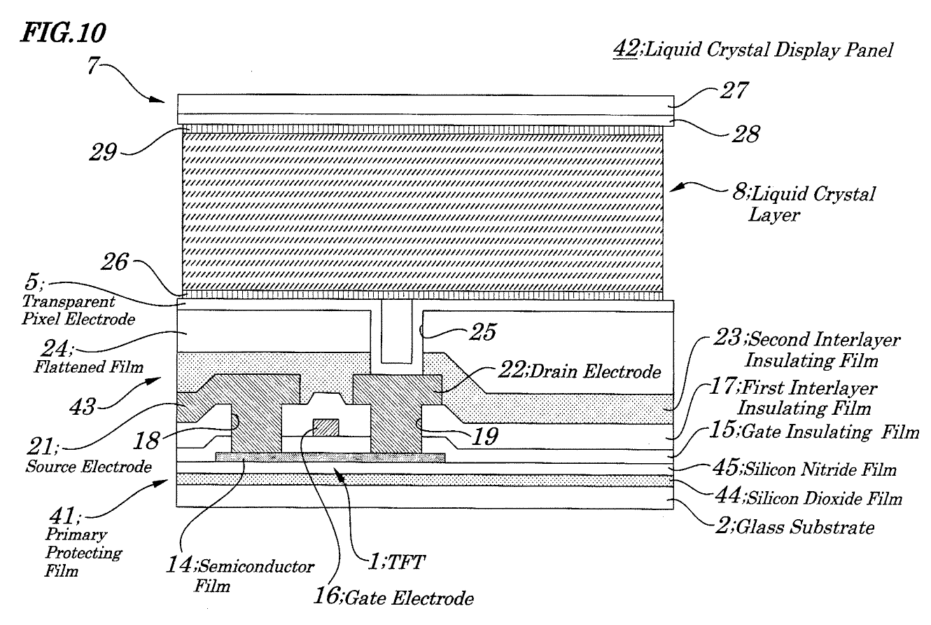

FIG. 10 is a cross-sectional view showing configurations of a liquid crystal display panel using a TFT as a switching element according to a third embodiment of the present invention. The liquid crystal display panel of the third embodiment differs from that of the first exemplary embodiment in that a primary protecting film is made up of a silicon dioxide film and a silicon nitride film. Configurations other than described above are approximately the same as those of the first exemplary embodiment and, in FIG. 9, same reference numbers are assigned to components having the same functions as in the first exemplary embodiment in FIG. 3 and their descriptions are described simply accordingly.

The TFT 1 of the third embodiment, as shown in FIG. 10, is formed on a glass substrate 2 with a primary protecting film 41 interposed between the TFT 1 and the glass substrate 2 and the formed TFT 1 is used as a switching element in the transmission-type liquid crystal display panel 42. The liquid crystal display panel 42 includes the TFT substrate 43 on which a large number of TFTs 1, 2, . . . , and a large number of the transparent pixel electrodes 5, 5, . . . , are formed, a facing substrate 7 placed in a fixed manner to face the TFT substrate 43 with a gap of several μm being sandwiched between the TFT 43 and the facing substrate 7, a liquid crystal layer 8 sealed hermetically in the above gap, and a pair of polarizers (not shown) placed outside the TFT substrate 43 and the facing substrate 7.

The TFT substrate 43 includes the glass substrate 2, the primary protecting film 41 formed on the glass substrate 2 and made of the silicon dioxide film (SiO₂) and silicon nitride film (for example, Si₃N₄) to prevent the contamination caused by B (boron), Na (sodium), or a like diffused from the glass substrate 2, a semiconductor film 14 made of polycrystalline silicone (p-Si) etched on the primary protecting film 43 so as to form an island structure on which a source region 11, drain region 12, and channel region 13 are formed, a gate insulating film 15 made of silicon dioxide film deposited on the semiconductor film 14, a gate electrode 16 formed on a region corresponding to the channel region 13 on the gate insulating film 15, the first interlayer insulating film 17 made of a silicon dioxide film deposited to cover the gate insulating film 15 and gate electrode 16, a source electrode 21 formed on the first interlayer insulating film 17 connected to the source region 11 through a contact hole 18, a drain electrode 22 also formed on the first interlayer insulating film 17 connected to the drain region 12 through a contact hole 19, the second interlayer insulating film 23 made of a silicon nitride film formed in a manner to cover the first interlayer insulating film 17, source electrode 21, and drain electrode 22, a flattened film 24 made of an organic material of an acrylic resin formed on the second interlayer insulating film 23, and a transparent pixel electrode layer (ITO film) 5 connected to the drain electrode 22 through a contact hole 25.

That is, the TFT 1 has the semiconductor film 14 on which the source region 11, the drain region 12, and the channel region 13 are formed, the gate insulating film 15 made of a silicon dioxide film deposited on the semiconductor film 14, and the gate electrode 16 formed in the region corresponding to the channel region 13 on the gate insulating film 15. On the transparent pixel electrode layer 5 is formed a liquid crystal orientation film 26 in a manner to cover the transparent pixel electrode layer 5. Moreover, the facing substrate 7 is configured so that a facing electrode 28 is formed on a transparent insulating substrate 27. On the facing electrode 28 is formed a liquid crystal orientation film 29 in a manner to cover the facing electrode 28. The TFT substrate 43 and the facing substrate 7 are so arranged that the liquid crystal orientation film 26 faces the liquid crystal orientation film 29 and the liquid crystal layer 8 is sandwiched between the liquid crystal orientation film 26 and the liquid crystal orientation film 29. The primary protecting film 41 of the third embodiment is so configured that a silicon dioxide film 44 is stacked on a silicon nitride film 45 wherein the silicon dioxide film 44 is made of silicon dioxide whose content of occluded water is suppressed.

Thus, by configuring as above, in the third embodiment, the same effect as obtained in the first exemplary embodiment can be achieved as well. Additionally, since the primary protecting film 41 is made of the silicon dioxide film 44 and silicon nitride film 45, the contamination caused by boron (B), sodium (Na), or a like diffused from the glass substrate 2 can be more reliably prevented.

### Fourth Embodiment

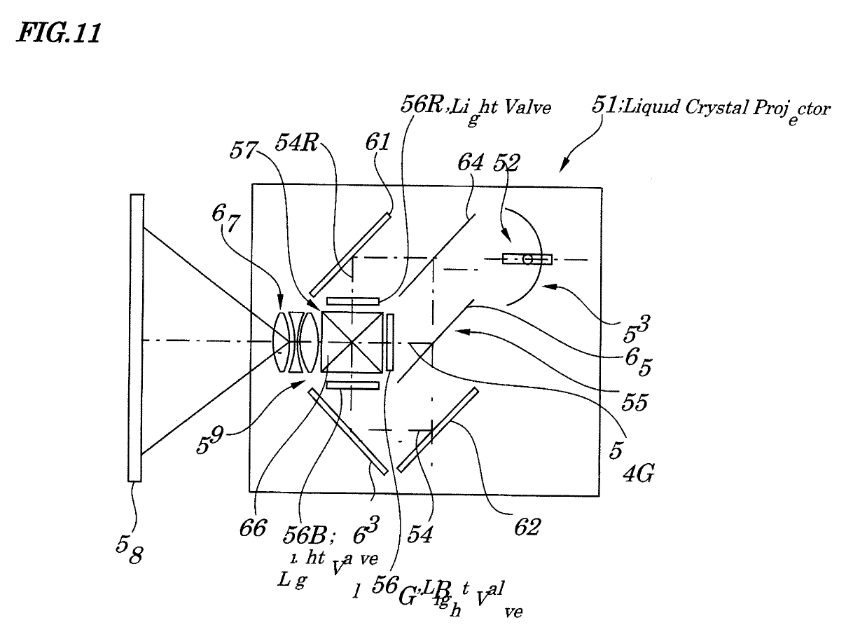

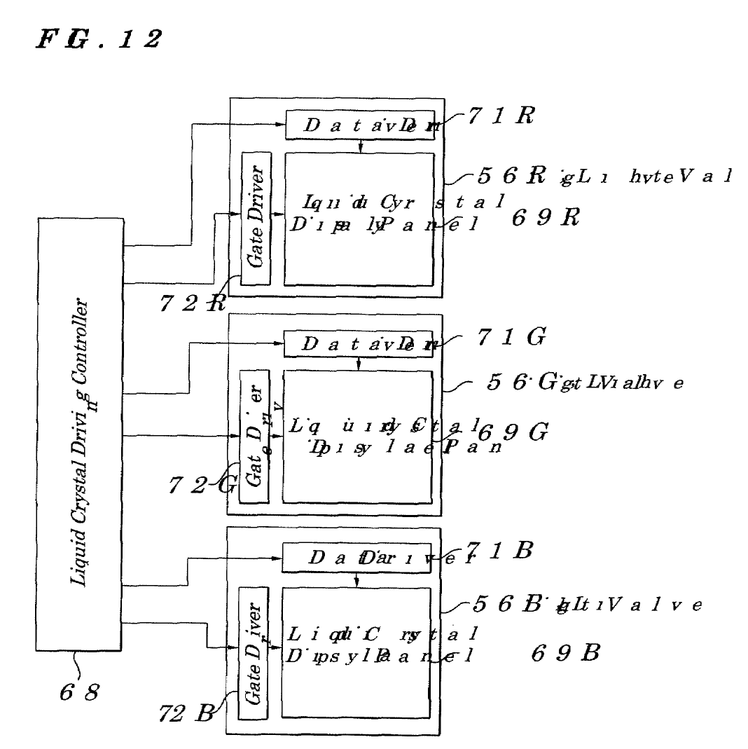

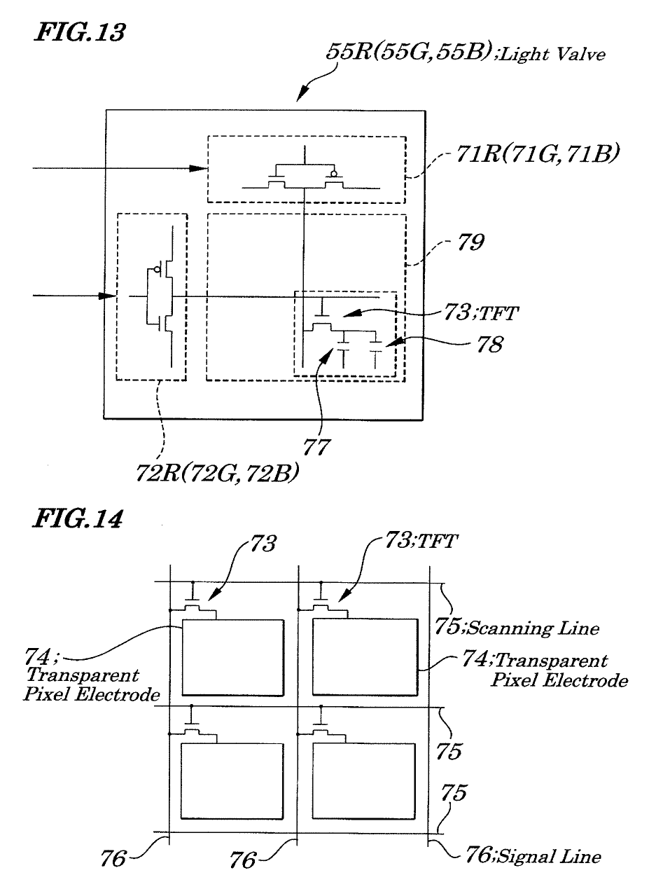

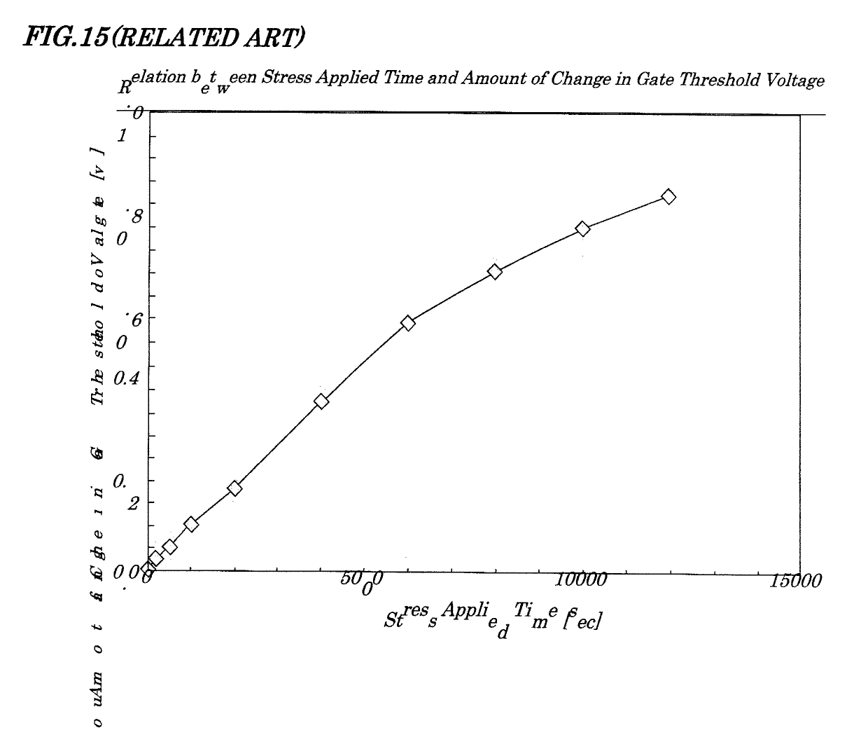

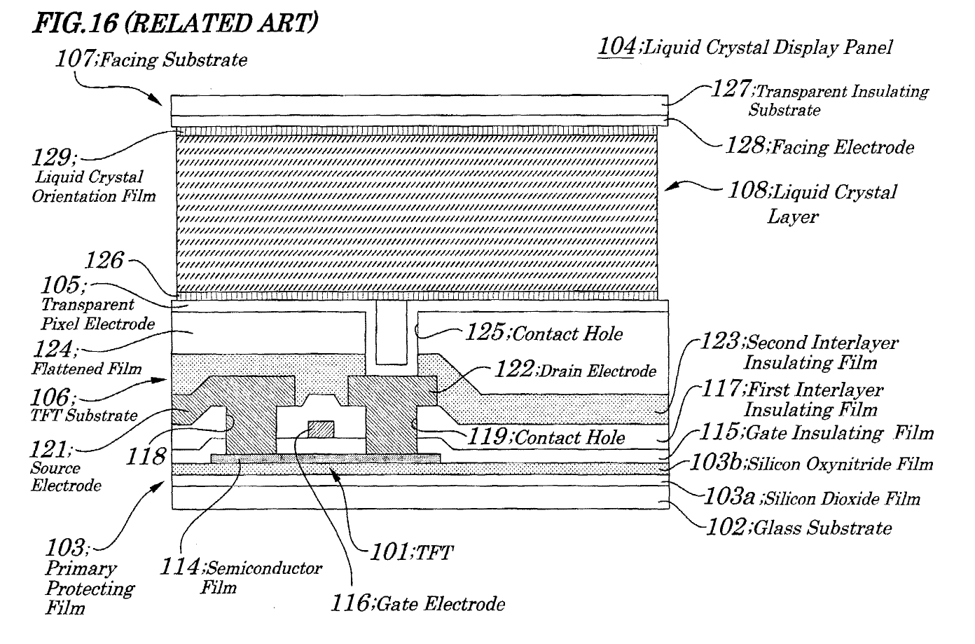

FIG. 11 is a block diagram of a liquid crystal projector using, as a light valve, a liquid crystal display panel of a fourth embodiment of the present invention. FIG. 12 is a diagram explaining configurations of the liquid crystal projector. FIGS. 13 and 14 are equivalent circuit diagrams explaining the light valve in the liquid crystal projector. The above liquid crystal projector 51 includes, as shown in FIG. 11, a halogen lamp 52 serving as a light source, a reflecting mirror 53 made up of, for example, elliptic mirrors, a color separating optical system 55 to separate white light emitted from the halogen lamp 52 into three luminous fluxes 54R, 54G, and 55B each for a single color out of three primary colors of red, green, and blue for emission, light valves 56R, 56G, and 56B to respectively transmit and intercept red light, green light, and blue light, a color synthesizing optical system 57 to respectively synthesize colors having transmitted through the light valves 56R, 56G, and 56B, and a projection light optical system 59 to project synthesized light on a screen.

The color separating optical system 55, as shown in FIG. 11, has mirrors 61, 62, and 63 and dichroic mirrors 64 and 65. The color synthesizing optical system 57 has a dichroic prism. The projection light optical system 59 has a projection lens to project, in an expanded manner, synthesized light on the screen 58. Moreover, each of the light valves 56R, 56G, and 56B is made up of the liquid crystal display panel having the TFT substrate of the first to third embodiments.

The light valves 56R, 56G and 56B, as shown in FIG. 12, are driven by a liquid crystal driving controller 68 and include, respectively, the liquid crystal display panels 69R, 69G, and 69B, data drivers (electrode driving circuits) 71R, 71G, and 71B to supply display signals (data signals) to each signal line 76, and gate drivers (scanning electrode driving circuits) 72R, 72G, and 72B to supply scanning signals to each scanning line 75.

Each of the liquid crystal display panels 69R, 69G, and 69B, as shown in FIGS. 13 and 14, has a TFT substrate on which a large number of TFTs 73, 73, . . . each serving as a switching element and a large number of transparent pixel electrodes 74, 74, . . . are formed, a facing substrate placed in a fixed manner to face the TFT substrate with a gap of several μm being sandwiched between the TFT substrate and facing substrate, and a liquid crystal layer sealed in the gap. Moreover, in FIG. 13, the reference number 77 shows a liquid crystal capacitor and the reference number 78 shows a holding capacitor connected, in parallel, to the liquid crystal capacitor. The liquid crystal layer is controlled in every pixel 79 according to an applied voltage so as to obtain a desired transmittance rate. On the TFT substrate are placed a large number of transparent pixel electrodes 74, 74, . . . in a matrix form and in portions surrounding the transparent pixel electrodes 74, 74, . . . are placed each of scanning lines 75 to supply a scanning signal and each of displaying lines 76 to supply a displaying signal so as to be orthogonal to one another.

Each of the TFTs 73 is configured to be placed in a portion neighboring to each intersection point of each of the scanning lines 75 and each of signal lines 76 and a drain electrode of each of the TFTs 73 is connected to each of transparent pixel electrodes 74 to apply a signal charge to a corresponding cell and is used as a switching element. Each of the TFTs 73 is driven and controlled by an input of a scanning signal from each of the gate drivers (scanning electrode driving circuits) 72R, 72G, and 72B via each of the scanning lines 75 to a gate electrode connected to each of the scanning lines and by an input of a displaying signal (data signal) from each of the data drivers 71R, 71G, and 71B to a source electrode connected to each of the signal lines 76. Moreover, a drain electrode of each of the TFTs 73 is connected to each of the transparent pixel electrodes 74 via a contact hole.

Thus, according to the configurations of the TFT in the liquid crystal display panel used as the light valve in the fourth embodiment, since the primary protecting film whose film quality has been changed and improved by hydrogen plasma processing is used, secular changes in characteristics are small, thus ensuring high reliability. Also, since the primary protecting film of the TFT substrate does not contain a silicon oxynitrized film, no lowering of the transmittance rate occurs, which serves to avoid adverse effects on optical characteristics.

It is apparent that the present invention is not limited to the above embodiments but may be changed and modified without departing from the scope and spirit of the invention. For example, in the above embodiments, aluminum is used for a metal film making up the gate electrode, however, instead of aluminum, metal such as chromium, molybdenum, tungsten, tantalum or a like and alloys containing these metals including aluminum as a main constituent may be employed.

Also, the gate electrode may be configured so as to have a two-layered structure made up of a metal layer and a polycrystalline film or microcrystalline silicon film. Amorphous silicon or polycrystalline germanium may be used. Moreover, instead of the LPCVD method or the PECVD method, an atmospheric CVD method can be selected. Furthermore, the insulating film or the like may be formed by using an ALD (Atomic-Layer Deposition) method, instead of the CVD method.

Additionally, the TFT substrate on which the TFT of the present invention is formed may be used for a reflective type or semi-transmission panel, in addition to the transmission type liquid crystal display panel. Also, the TFT substrate of the present invention may be used not only for the liquid crystal display panel but also for EL panels. The liquid crystal panel having the TFT of the present invention may be used as a light valve in front-projection-type data projectors, front-projection-type home projectors, rear-projection-type home projectors, or a like.

What is claimed is:

1. A method for manufacturing a semiconductor device comprising:
a process of forming a primary protecting film on a substrate; and
a process of forming an active layer on the formed primary protecting film,
wherein hydrogen plasma processing is added by which said substrate, on which at least said primary protecting film is formed, is exposed to hydrogen plasma and occluded water contained in said primary protecting film is desorbed and removed.

2. The method for manufacturing the semiconductor device according to claim 1, wherein, in said hydrogen plasma processing, said substrate is exposed to hydrogen plasma by setting a temperature of said substrate to be within a range between 350° C. and 420° C.

3. The method for manufacturing the semiconductor device according to claim 1, wherein, in said hydrogen plasma processing, treating time is set to be within a range of 3 minutes to 60 minutes.

4. The method for manufacturing the semiconductor device according to claim 1, wherein said hydrogen plasma processing is performed so as to acquire quality of said primary protecting film to a degree to which a content of occluded water is less than that of structural water.

5. The method for manufacturing the semiconductor device according to claim 1, wherein said hydrogen plasma processing is performed in a manner in which, in said hydrogen plasma processing, atoms each having a mass number of 18 that are desorbed from said primary protecting film at a time of being heated is counted and in a manner in which, in an increased temperature—desorbed amount profile obtained by Thermal Desorption Spectroscopy, a first peak of a desorbed amount appears in a first temperature range between at least 150° C. and 250° C. and a second peak of a desorbed amount appears in a second temperature range between 250° C. and 400° C.

6. The method for manufacturing the semiconductor device according to claim 1, further comprising:
a protecting film forming process of forming said primary protecting film on said substrate;
an active layer forming process of forming an active layer made of a semiconductor film so as to have a desired pattern on said primary protecting film;
an insulating forming process of forming a gate insulating film on said active layer;
a gate electrode forming process of forming a gate electrode on said gate insulating film;
an impurity implanting process of implanting an impurity ion into said active layer using said gate electrode as a mask; and
an annealing process of activating an impurity ion implanted into said active layer by specified heating treatment to form a source region and drain region;
wherein said hydrogen plasma processing process is performed after said annealing process.

7. The method for manufacturing the semiconductor device according to claim 1, wherein said hydrogen plasma processing is performed, after the formation of said primary protecting film and before the formation of said active layer.

8. The method for manufacturing the semiconductor device according to claim 1, wherein said primary protecting film having a two-layered structure is formed by depositing an upper protecting film made of silicon nitride after the formation of a primary protecting film made of silicon dioxide.

9. The method for manufacturing the semiconductor device according to claim 1, wherein said substrate comprises a glass substrate.

10. The method for manufacturing the semiconductor device according to claim 1, wherein said semiconductor is made of polycrystalline silicon.

11. The method for manufacturing the semiconductor device according to claim 1, wherein, by using a Low Pressure Chemical Vapor Deposition method using silane and oxygen as material gas or a Plasma Enhanced Vapor Deposition method using silane and di-nitrogen monoxide as material gas, a silicon dioxide film serving as said primary protecting film is formed on said substrate and said active layer made of said semiconductor is formed on said primary protecting film and, at least after the formation of said active layer, said hydrogen plasma processing is performed.

12. A semiconductor device comprising:
a primary protecting film formed on a substrate; and
an active layer made of a semiconductor formed on said primary protecting film,
wherein said primary protecting film has a characteristic in which a content of occluded water is less than that of structural water.

13. The semiconductor device according to claim 12, wherein said semiconductor device is obtained by exposing said substrate, on which at least said primary protecting film is formed, to hydrogen plasma and by performing hydrogen plasma processing by which a content of occluded water contained in said primary protecting film is desorbed and removed.

14. The semiconductor device according to claim 12, wherein said primary protecting film comprises a silicon dioxide film formed on said substrate by a Low Pressure Chemical Vapor Deposition method using silane and oxygen as material gas or by a Plasma Enhanced Chemical Vapor Deposition method using silane and di-nitrogen monoxide as material gas.

15. The semiconductor device according to claim 12, wherein said substrate comprises a glass substrate.

16. The semiconductor device according to claim 12, wherein said semiconductor is made of polycrystalline silicon.

17. The semiconductor device according to claim 12, wherein said primary protecting film comprises a two-layered structure having a lower layer protecting film made of silicon dioxide and an upper layer protecting film made of silicon nitride.

18. A semiconductor device comprising:
a primary protecting film formed on a substrate; and
an active layer made of a semiconductor formed on said primary protecting film;
wherein, in an increased temperature—desorbed amount profile obtained by Thermal Desorption Spectroscopy in which atoms each having a mass number of 18 that are desorbed from said primary protecting film at a time of being heated is counted, a film quality of said primary protecting film is achieved in a manner in which a first peak of desorbed amount appears in a first temperature range between at least 150° C. and 250° C., in which a second peak of desorbed amount appears in a second temperature range between 250° C. and 400° C. and in which the first peak appearing in said first temperature range is less than the second peak appearing in said second temperature range.

19. The semiconductor device according to claim 18, wherein said semiconductor device is obtained by exposing said substrate, on which at least said primary protecting film is formed, to hydrogen plasma and by performing hydrogen plasma processing by which a content of occluded water contained in said primary protecting film is desorbed and removed.

20. The semiconductor device according to claim 18, wherein said semiconductor device is obtained by performing hydrogen plasma processing to expose said substrate, on which at least said primary protecting film is formed, to hydrogen plasma so as to desorb and remove occluded water contained in said primary protecting film to a degree to which the first peak appearing within said first temperature range is less than the second peak appearing within said second temperature range in said increased temperature—desorbed amount profile.

21. The semiconductor device according to claim 19, wherein said hydrogen plasma processing is performed by setting a temperature of said substrate on which said primary protecting film is formed to be between 350° C. and 420° C. and by exposing said substrate to hydrogen plasma.

22. The semiconductor device according to claim 19, wherein, in said hydrogen plasma processing, treating time is set to be within a range of 3 minutes to 60 minutes.

23. The semiconductor device according to claim 18, wherein said primary protecting film comprises a silicon dioxide film formed on said substrate by a Low Pressure Chemical Vapor Deposition method using silane and oxygen as material gas or by a Plasma Enhanced Chemical Vapor Deposition method using silane and di-nitrogen monoxide as material gas.

24. The semiconductor device according to claim 18, wherein said substrate comprises a glass substrate.

25. The semiconductor device according to claim 18, wherein said semiconductor is made of polycrystalline silicon.

26. The semiconductor device according to claim 18, wherein said primary protecting film comprises a two-layered structure having a lower layer protecting film made of silicon dioxide and an upper layer protecting film made of silicon nitride.
